(19) United States
(12) Patent Application Publication
(10) Pub. No.: US 2009/0289274 A1
(43) Pub. Date: Nov. 26, 2009

(54) PACKAGE STRUCTURE OF LIGHT EMITTING DIODE AND METHOD OF MANUFACTURING THE SAME

(75) Inventor: Byoung Jae Park, Gwangju (KR)

Correspondence Address: MITCHELL P. BROOK;LUCE, FORWARD, HAMILTON & SCRIPPS LLP, 11988 EL CAMINO REAL, SUITE 200, SAN DIEGO, CA, 92130, US

(73) Assignee: SAILUX, INC., Gwangju (KR)

(21) Appl. No.: 12/293,423

(22) PCT Filed: Mar. 23, 2007
(86) PCT No.: PCT/KR07/01449

§ 371 Date: Sep. 17, 2008

(30) Foreign Application Priority Data
Mar. 23, 2006 (KR) 10-2006-0026702

(51) Int. Cl. H01L 33/00; H01L 21/50

(52) U.S. Cl. 257/99; 438/26; 257/E33.056; 257/E21.499

(57) ABSTRACT

Provided are a LED package structure and a method of manufacturing the same. The LED package structure includes first and second plate-shaped auxiliary support pieces; a heat-dissipating portion formed upwardly higher than the first and second auxiliary support pieces; a plurality of auxiliary leads connected between each of the auxiliary support pieces and a side surface of the heat-dissipating portion, a portion of each of the plurality of auxiliary leads adjacent to the heat-dissipating portion extending along the same level with the top surface of the heat-dissipating portion; and main leads extending from the auxiliary support pieces to the heat-dissipating portion along the same level with the top surface of the auxiliary leads and spaced apart from the heat-dissipating portion, wherein the heat-dissipating portion, the auxiliary support pieces and the main leads are integrally formed using a conductive metallic material. According to the LED package structure, connection leads are integrally formed with a heat-dissipating portion through perforating or bending a metal plate whose central part is thicker than its peripheral part, followed by molding and cutting process, thereby facilitating and simplifying the manufacturing process.

### TECHNICAL FIELD

The present invention relates to a package structure of a light emitting diode (LED) and a method of manufacturing the same, and more particularly, to an LED package structure, a method of manufacturing the LED package structure, and a method of manufacturing an LED adopting the manufacturing method of the LED package structure.

### BACKGROUND ART

With the recent introduction of a structure capable of creating and radiating white light using fluorescent substance, the application range of a light emitting diode (“LED”) has been extended to the field of illumination capable of substituting for conventional lighting, let alone a simple light-emitting display function. Thus, research has been steadily undertaken on an LED for high-output applications such as lighting.

As the temperature increases over rated operating temperature, the life span and light emitting efficiency of an LED, which is one of semiconductor devices, are reduced. As a result, to improve the output of the LED, there is a need for a heat-dissipating structure capable of operating at as low an operating temperature as possible by effectively dissipating heat generated in the LED.

However, a conventional LED is constructed such that a plate-shaped lead frame has an LED chip mounted thereon. Since heat dissipation is made through the lead frame, the conventional LED has poor heat-dissipation capability and is thus difficult to apply to high-output applications.

To address these problems, development of a variety of LED package structures having a large heat-dissipation plate is under way. However, most of known LED package structures are constructed such that a heat-dissipation plate and a lead frame are separately formed and then assembled to each other, resulting in complexity in the manufacturing process.

### DISCLOSURE OF INVENTION

### Technical Problem

To solve the above problems, the present invention provides a light emitting diode (LED) package structure that is easy to manufacture while improving heat-dissipation capability, a method of manufacturing the LED package structure, and a method of manufacturing a light emitting device adopting the same.

### Technical Solution

According to an aspect of the present invention, there is provided a light emitting diode (LED) package structure comprising: first and second plate-shaped auxiliary support pieces each having a first thickness; a heat-dissipating portion used to mount a light emitting diode chip and formed upwardly higher than the first and second auxiliary support pieces at the center of the first and second auxiliary support pieces, the heat-dissipating portion having a second thickness greater than the first thickness; a plurality of auxiliary leads having the same thicknesses as the auxiliary support pieces and connected between each of the auxiliary support pieces and a side surface of the heat-dissipating portion, a portion of each of the plurality of auxiliary leads adjacent to the heat-dissipating portion extending along the same level with the top surface of the heat-dissipating portion; and main leads having the same thicknesses as the auxiliary support pieces, extending from the auxiliary support pieces to the heat-dissipating portion along the same level with the top surface of the auxiliary leads, a portion of each main lead adjacent to the heat-dissipating portion extending along the same level with the top surface of the heat-dissipating portion to be spaced apart from the heat-dissipating portion, wherein the heat-dissipating portion, the auxiliary support pieces and the main leads are integrally formed using a conductive metallic material.

Preferably, the auxiliary leads and the main leads are respectively configured to have first horizontal portions extending from the heat-dissipating portion along the same level with the top surface of the heat-dissipating portion by a predetermined length, vertical portions bent downward from the first horizontal portions, and second horizontal portions extending from distal ends of the vertical portions along the same level with the bottom surface of the heat-dissipating portion to then be connected to the auxiliary support pieces.

In addition, the LED package structure may further comprise a chip mounting portion whose inner diameter gradually decreases toward a lower position at the center of the heat-dissipating portion to mount the LED chip.

Also, the LED package structure may further comprise a molding cap including portions of the auxiliary leads and the main leads in view of the heat-dissipating portion, wherein the molding cap is formed through molding such that the bottom surface of the heat-dissipating portion, parts of the top surface of the first horizontal portions of the main leads, and the chip mounting portion are exposed outside.

According to another aspect of the present invention, there is provided a method of manufacturing a light emitting diode (LED) package structure, the method comprising: forming auxiliary leads and main leads by performing a perforating process on a base frame having a base portion with a first thickness and a heat-dissipating portion extending downwardly from the base portion and having a second thickness greater than the first thickness at the center of the base portion, the perforating process performed on the base portion of the base frame, the auxiliary leads each connected between opposite ends of the base portion and the heat-dissipating portion, and the main leads each having one end isolated from the heat-dissipating portion and the other end connected to the end of the base portion; and forming structures of the auxiliary leads and main leads such that first horizontal portions extend from the heat-dissipating portion along the same level with the top surface of the heat-dissipating portion by a predetermined length, vertical portions are bent downward from the first horizontal portions, and second horizontal portions extending from distal ends of the vertical portions along the same level with the bottom surface of the heat-dissipating portion.

Preferably, the method of manufacturing the LED package structure may further comprise forming a chip mounting portion whose inner diameter gradually decreases toward a lower position at the center of the heat-dissipating portion.

In addition, the method of manufacturing the LED package structure may further comprise forming a molding cap including a portion of the heat-dissipating portion and portions of the auxiliary leads and the main leads, the molding cap formed through molding such that the first horizontal portions of the main leads and the chip mounting portion are exposed outside.

The method of manufacturing the LED package structure may further comprise cutting the main leads and the auxiliary leads exposed outside from the molding cap.

According to still another aspect of the present invention, there is provided a method of manufacturing a light emitting device, the method comprising: forming auxiliary leads and main leads by performing a perforating process on a base frame having a base portion with a first thickness and a heat-dissipating portion extending downwardly from the base portion and having a second thickness greater than the first thickness, the base frame having a chip mounting portion formed at the center of its top surface, the perforating process performed on the base portion of the base frame, the auxiliary leads each connected between opposite ends of the base portion and the heat-dissipating portion, and the main leads each having one end isolated from the heat-dissipating portion and the other end connected to the end of the base portion; forming a molding cap including a portion of the heat-dissipating portion and portions of the auxiliary leads and the main leads, the molding cap formed through molding such that the main lead portion adjacent to the heat-dissipating portion and the chip mounting portion are exposed outside together; and forming structures of the auxiliary leads and main leads such that first horizontal portions extend along the same level with the top surface of heat-dissipating portion to be spaced apart from the molding cap by a predetermined distance, vertical portions are bent downward from the first horizontal portions, and second horizontal portions extend from distal ends of the vertical portions along the same level with the bottom surface of the heat-dissipating portion.

According to a further aspect of the present invention, there is provided a method of manufacturing a light emitting device, the method comprising: forming auxiliary leads and main leads by performing a perforating process on a base frame having a base portion with a first thickness and a heat-dissipating portion extending downwardly from the base portion and having a second thickness greater than the first thickness, the base frame having a chip mounting portion formed at the center of its top surface, the perforating process performed on the base portion of the base frame, the auxiliary leads each connected between opposite ends of the base portion and the heat-dissipating portion, and the main leads each having one end isolated from the heat-dissipating portion and the other end connected to the end of the base portion; forming structures of the auxiliary leads and main leads such that first horizontal portions extend from the heat-dissipating portion along the same level with the top surface of the heat-dissipating portion by a predetermined length, vertical portions are bent downward from the first horizontal portions, and second horizontal portions extend from distal ends of the vertical portions along the same level with the bottom surface of the heat-dissipating portion; forming a molding cap including a portion of the heat-dissipating portion and portions of the auxiliary leads and the main leads, the molding cap formed through molding such that the first horizontal portions extending along the same level with the top surface of the heat-dissipating portion and the chip mounting portion are partially exposed outside from the vertical portions together with the chip mounting portion; and mounting a light emitting diode (LED) chip on the chip mounting portion and wire-bonding the LED chip and the first horizontal portions of the main leads to each other.

### BRIEF DESCRIPTION OF THE DRAWINGS

FIG. 1 is a perspective view of a light emitting diode (LED) package structure according to an embodiment of the present invention;

FIG. 2 is a perspective view of a base frame for forming the LED package structure shown in FIG. 1;

FIG. 3 is a plan view of a structure resulting after primarily processing the base frame shown in FIG. 2;

FIG. 4 is a plan view illustrating a state in which a chip mounting portion is formed on a heat-dissipating portion shown in FIG. 3;

FIG. 5 is a perspective view of a light emitting device according to an embodiment of the present invention, to which a molding cap as a modified example of the LED package structure of FIG. 1 is applied;

FIG. 6 is a perspective view of a light emitting device according to an another embodiment of the present invention;

FIG. 7 is a perspective view illustrating a state in which a molding cap is formed on the LED package structure of FIG. 6 and a lead is then cut; and

FIG. 8 is a plan view of an LED package structure according to still another embodiment of the present invention.

### BEST MODE FOR CARRYING OUT THE INVENTION

Hereinafter, a light emitting diode (LED) package structure which can be easily manufactured and has a heat-dissipating structure suitable for high-output applications, a method of manufacturing the LED package structure, and a method of manufacturing a light emitting device adopting the same, will be described in detail with reference to the attached drawings.

FIG. 1 is a perspective view of a light emitting diode (LED) package structure according to an embodiment of the present invention.

Referring to FIG. 1, an LED package structure 100 includes a heat-dissipating portion 110, auxiliary support pieces 121 and 122, main leads 131 and 132, and auxiliary leads 141 and 142.

The heat-dissipating portion 110 is formed of a substantially rectangular shape and has a chip mounting portion 111 whose inner diameter gradually decreases toward a lower position at a center of the heat-dissipating portion 110. The chip mounting portion 111 is used as an area where the LED chip is mounted.

A thickness, e.g., a second thickness, of the heat-dissipating portion 110 is greater than that of the auxiliary support piece 121, 122 and determined in consideration of heat-dissipation capability of an LED chip to which the heat-dissipating portion 110 is to be applied to.

The auxiliary support pieces 121, 122 have a thickness, e.g., a first thickness.

The auxiliary support pieces, i.e., a first and a second auxiliary support pieces, 121 and 122, are spaced a predetermined distance apart from the left and right side of the heat-dissipating portion 110 to support the auxiliary leads 141 and 142 and the main leads 131 and 132. The first and second auxiliary support pieces 121 and 122 are removed together with some of the main leads 131 and 132 and the auxiliary leads 141 and 142 after forming a molding cap 310, which will later be described.

The auxiliary leads 141 and 142 have the same thicknesses as the auxiliary support pieces 121 and 122 and connected between each of the auxiliary support pieces 121 and 122 and the heat-dissipating portion 110 in a strip shape.

In addition, the auxiliary leads 141 and 142 are formed at opposite sides of the main leads 131 and 132.

The auxiliary leads 141 and 142 have bent portions formed therebetween. In more detail, the bent portions include first horizontal portions 141a and 142a extending from either proximal end of the heat-dissipating portion 110 along the same level with the top surface of the heat-dissipating portion 110 by a predetermined length, vertical portions 141b and 142b extending downward from the first horizontal portions 141a and 142a, and second horizontal portions 141c and 142c extending from the vertical portions 141b and 142b along the same level with the bottom surface of the heat-dissipating portion 110.

The main leads 131 and 132 have the same thicknesses as the auxiliary support pieces 121 and 122.

The main leads 131 and 132 are spaced apart from the heat-dissipating portion 110 and have bent portions configured so as to correspond to those of the auxiliary leads 141 and 142.

That is to say, the bent portions of the main leads 131 and 132 include first horizontal portions 131a and 132a extending along the same level with the top surface of the heat-dissipating portion 110 by a predetermined length to either distal end of the main leads 131 and 132 spaced apart from the heat-dissipating portion 110, vertical portions 131b and 132b extending downward from the first horizontal portions 131a and 132a, and second horizontal portions 131c and 132c extending along the same level with the bottom surface of the heat-dissipating portion 110.

Here, the top surfaces of the first horizontal portions 131a and 132a are used for wire bonding and bottom surfaces of the second horizontal portions 131c and 132c are used for electrical connection with external circuitry.

The aforementioned LED package structure 100 is preferably coated with a material having high reflectivity. Preferably, the LED package structure 100 is formed of a multi-coated layer primarily coated with a nickel (Ni) and then secondarily coated with silver (Ag) on the nickel-coated layer.

A method of manufacturing the LED package structure 100 will now be described.

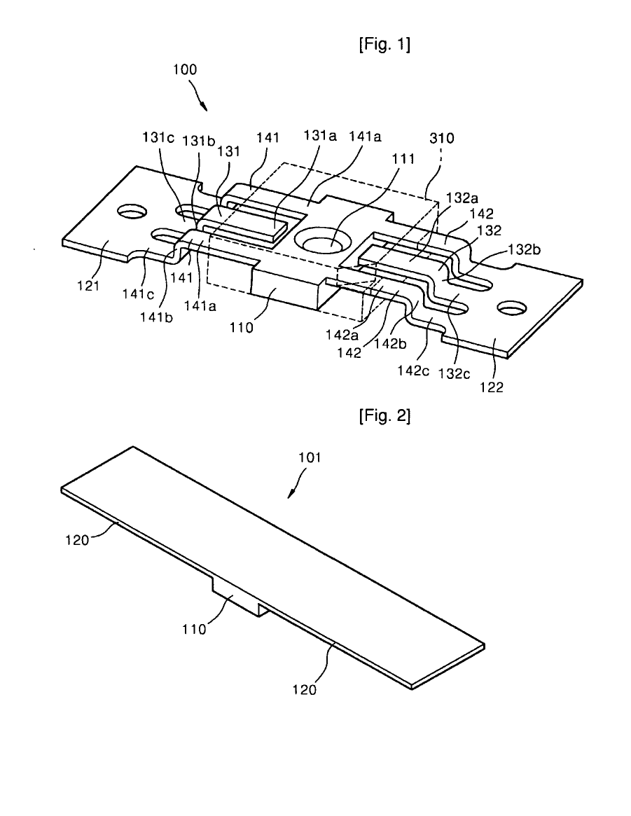

In order to manufacture the LED package structure 100, a base frame 101 having such a shape as shown in FIG. 2 is used.

In more detail, the base frame 101 has a base portion 120 with a first thickness and a heat-dissipating portion 110 disposed at the center of the base portion 120 and extending a predetermined length downward relative to the base portion 120.

The base frame 101, which is shaped of an upside-down hat, may be formed by rolling, roll forming or extruding.

In addition, the base frame 101 is made of a material having superior heat and electric conductivity, e.g., copper or a copper alloy.

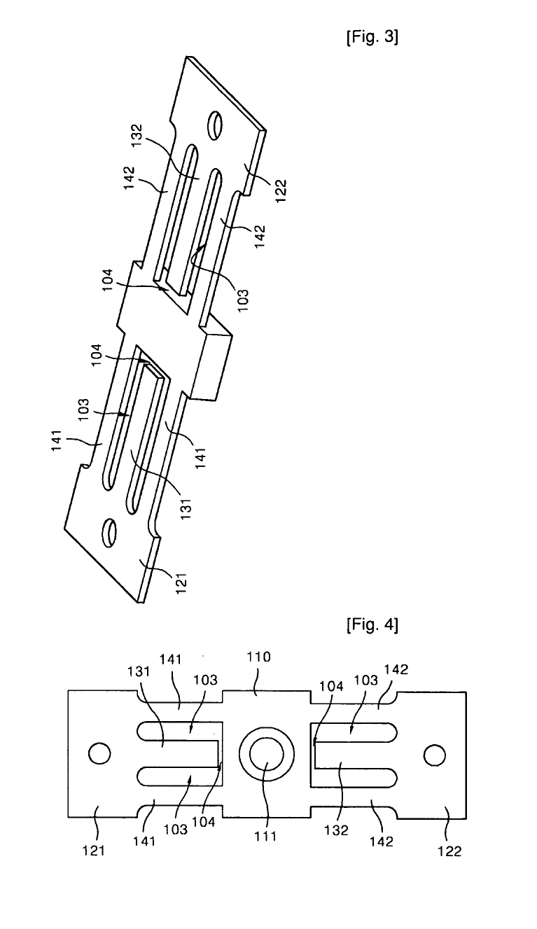

Referring to FIG. 3, a perforating process is performed on the base frame 101 to form the above-described auxiliary support pieces 121 and 122, the auxiliary leads 141 and 142, and the main leads 131 and 132. That is to say, the perforating process is performed so that an auxiliary lead formation slot 103 and a main lead isolation groove 104 are formed through the base frame 101. Then, as shown in FIG. 4, the chip mounting portion 111 is formed at the center of the heat-dissipating portion 110.

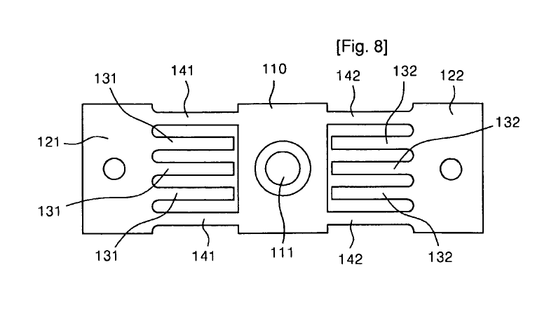

While the illustrated embodiment of the present invention has shown that the main leads 131 and 132 are formed at ether side of the center of the heat-dissipating portion 110, the invention is not limited to the illustrated example and may also be applied to a structure in which a plurality of main leads may be formed at both sides of the center of the heat-dissipating portion 110, as shown in FIG. 8.

Although not shown, in order to facilitate cutting portions to be cut after forming a molding cap followed by forming the auxiliary leads 141 and 142 and the main leads 131 and 132, cutting guide grooves may also be formed in the perforating process.

Then, the perforated base frame 101, as shown in FIG. 4, is constructed to have a structure shown in FIG. 1 by bending the auxiliary leads 141 and 142 and the main leads 131 and 132. The bending of the auxiliary leads 141 and 142 and the main leads 131 and 132 may be performed after the coating or the forming of the molding cap.

Next, in order to improve reflection efficiency from light emitted from an internal surface of the LED chip to be mounted on the chip mounting portion 111 and wire-bondability, plating treatment is performed. A portion subjected to the plating treatment may include at least the chip mounting portion 111, and the main leads 131 and 132. In consideration of working efficiency, the overall LED package structure 100 may be subjected to the plating treatment.

Preferably, the LED package structure 100 is primarily plated with nickel (Ni) and then secondarily plated with silver (Ag).

After or before mounting the LED chip on the LED package structure 100, a portion indicated by a dotted line shown in FIG. 1 is molded using a resin to form the molding cap 310, the auxiliary leads 141 and 142 and the main leads 131 and 132, which are exposed outside from the molding cap 310, are cut. Here, the cutting is be appropriately performed such that the second horizontal portions 131c and 132c of the main leads 131 and 132 partially remain, the first horizontal portions 141a and 142a of the auxiliary leads 141 and 142, which protrude from the molding cap 310, may be cut, or the second horizontal portions 141c and 142c, which are for improve heat-dissipation capability, partially remain, which will now be described in more detail.

As a first method, a LED chip (not shown) is mounted on the chip mounting portion 111, and the first horizontal portions 131a and 132a of the main leads 131 and 132 and the LED chip are wire-bonded, followed by molding using a transparent resin such that the portion indicated by a dotted line shown in FIG. 1 forms an outline and cutting the auxiliary leads 141 and 142 and the main leads 131 and 132.

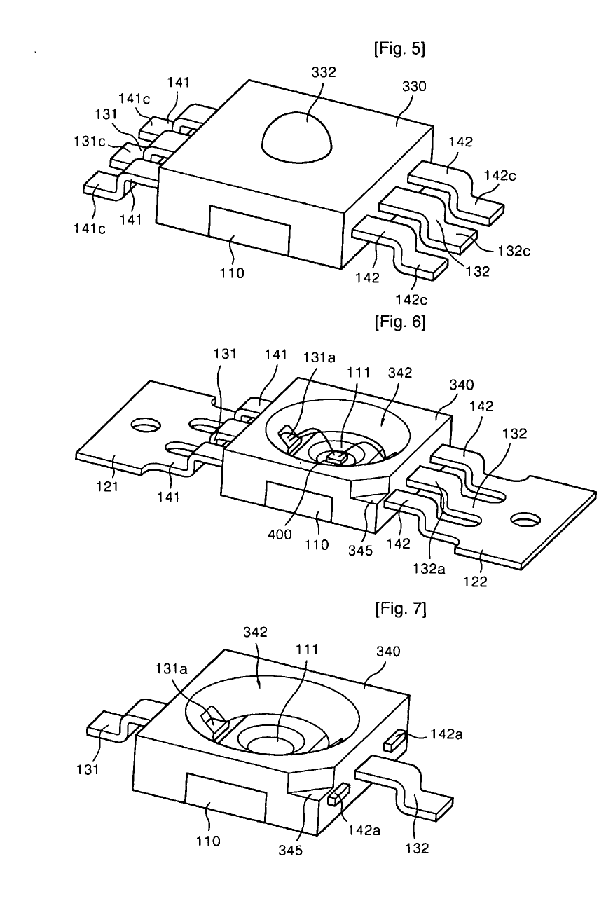

Here, the molding cap 310 formed by molding may have a planar top surface. Alternatively, as shown in FIG. 5, a molding cap 330 may be configured such that a lens 332 having a convexly projecting portion is formed at a portion corresponding to the chip mounting portion 111. While the embodiment illustrated in FIG. 5 has shown that the auxiliary leads 141 and 142 are cut such that the second horizontal portions 141c and 142c of the auxiliary leads 141 and 142 partially remain, the invention is not limited thereto and the auxiliary leads 141 and 142 may be cut so as not to protrude from the molding cap 330.

Alternatively, as a second method, as shown in FIG. 6, a molding cap 340 having a receiving groove 342 is formed by molding using a resin such that a portion including the first horizontal portions 131a and 132a of the main leads 131 and 132 and the chip mounting portion 111 are exposed. A LED chip 400 is mounted on the chip mounting portion 111 and each of the first horizontal portions 131a and 132a of the main leads 131 and 132 and the LED chip 400 are wire-bonded to each other. In this case, to enhance the surface reflectivity, the molding cap 340 is preferably made of a white resin.

After forming the molding cap 340, the LED chip 400 is hermetically sealed by filling the receiving groove 342 of the molding cap 340 with a transparent material or additionally providing an auxiliary cap (not shown) so as to have a lens-shaped configuration, as described above. Before or after forming the auxiliary cap, the main leads 131 and 132 and the auxiliary leads 141 and 142 are cut.

In the meanwhile, in a case where a white LED chip is employed to the LED package structure according to the present invention, after mounting and wire-bonding the white LED chip, a fluorescent substance is applied to the white LED chip to surround the same and then filled with transparent resin to form an auxiliary cap.

Reference numeral 345 denotes a marking chamfer portion for indicating polarity of each of the main leads 131 and 132.

Referring to FIG. 7, unlike in the foregoing discussion, after forming the molding cap 340, the main leads 131 and 132 and the auxiliary leads 141 and 142 are first cut, followed by chip mounting and forming the auxiliary cap.

As described above, according to the LED package structure of the present invention and the manufacturing method thereof, connection leads are integrally formed with a heat-dissipating portion through perforating or bending a metal plate whose central part is thicker than its peripheral part, followed by molding and cutting process, thereby facilitating and simplifying the manufacturing process.

1. A light emitting diode (LED) package structure comprising:
first and second plate-shaped auxiliary support pieces each having a first thickness;
a heat-dissipating portion used to mount a light emitting diode chip and formed upwardly higher than the first and second auxiliary support pieces at the center of the first and second auxiliary support pieces, the heat-dissipating portion having a second thickness greater than the first thickness;
a plurality of auxiliary leads having the same thicknesses as the auxiliary support pieces and connected between each of the auxiliary support pieces and a side surface of the heat-dissipating portion, a portion of each of the plurality of auxiliary leads adjacent to the heat-dissipating portion extending along the same level with the top surface of the heat-dissipating portion; and
main leads having the same thicknesses as the auxiliary support pieces, extending from the auxiliary support pieces to the heat-dissipating portion along the same level with the top surface of the auxiliary leads, a portion of each main lead adjacent to the heat-dissipating portion extending along the same level with the top surface of the heat-dissipating portion to be spaced apart from the heat-dissipating portion,
wherein the heat-dissipating portion, the auxiliary support pieces and the main leads are integrally formed using a conductive metallic material.

2. The LED package structure of claim 1, wherein the auxiliary leads and the main leads are respectively configured to have first horizontal portions extending from the heat-dissipating portion along the same level with the top surface of the heat-dissipating portion by a predetermined length, vertical portions bent downward from the first horizontal portions, and second horizontal portions extending from distal ends of the vertical portions along the same level with the bottom surface of the heat-dissipating portion to then be connected to the auxiliary support pieces.

3. The LED package structure of claim 2, further comprising a chip mounting portion whose inner diameter gradually decreases toward a lower position at the center of the heat-dissipating portion to mount the LED chip.

4. The LED package structure of claim 3, further comprising a molding cap including portions of the auxiliary leads and the main leads in view of the heat-dissipating portion, wherein the molding cap is formed through molding such that the bottom surface of the heat-dissipating portion, parts of the top surface of the first horizontal portions of the main leads, and the chip mounting portion are exposed outside.

5. A method of manufacturing a light emitting diode (LED) package structure, the method comprising:
forming auxiliary leads and main leads by performing a perforating process on a base frame having a base portion with a first thickness and a heat-dissipating portion extending downwardly from the base portion and having a second thickness greater than the first thickness at the center of the base portion, the perforating process performed on the base portion of the base frame, the auxiliary leads each connected between opposite ends of the base portion and the heat-dissipating portion, and the main leads each having one end isolated from the heat-dissipating portion and the other end connected to the end of the base portion; and
forming structures of the auxiliary leads and main leads such that first horizontal portions extend from the heat-dissipating portion along the same level with the top surface of the heat-dissipating portion by a predetermined length, vertical portions are bent downward from the first horizontal portions, and second horizontal portions extending from distal ends of the vertical portions along the same level with the bottom surface of the heat-dissipating portion.

6. The method of claim 5, further comprising forming a chip mounting portion whose inner diameter gradually decreases toward a lower position at the center of the heat-dissipating portion.

7. The method of claim 6, further comprising forming a molding cap including a portion of the heat-dissipating portion and portions of the auxiliary leads and the main leads, the molding cap formed through molding such that the first horizontal portions of the main leads and the chip mounting portion are exposed outside.

8. The method of claim 7, further comprising cutting the main leads and the auxiliary leads exposed outside from the molding cap.

9. A method of manufacturing a light emitting device, the method comprising:
forming auxiliary leads and main leads by performing a perforating process on a base frame having a base portion with a first thickness and a heat-dissipating portion extending downwardly from the base portion and having a second thickness greater than the first thickness, the base frame having a chip mounting portion formed at the center of its top surface, the perforating process performed on the base portion of the base frame, the auxiliary leads each connected between opposite ends of the base portion and the heat-dissipating portion, and the main leads each having one end isolated from the heat-dissipating portion and the other end connected to the end of the base portion;
forming a molding cap including a portion of the heat-dissipating portion and portions of the auxiliary leads and the main leads, the molding cap formed through molding such that the main lead portion adjacent to the heat-dissipating portion and the chip mounting portion are exposed outside together; and
forming structures of the auxiliary leads and main leads such that first horizontal portions extend along the same level with the top surface of heat-dissipating portion to be spaced apart from the molding cap by a predetermined distance, vertical portions are bent downward from the first horizontal portions, and second horizontal portions extend from distal ends of the vertical portions along the same level with the bottom surface of the heat-dissipating portion.

10. A method of manufacturing a light emitting device, the method comprising:
forming auxiliary leads and main leads by performing a perforating process on a base frame having a base portion with a first thickness and a heat-dissipating portion extending downwardly from the base portion and having a second thickness greater than the first thickness, the base frame having a chip mounting portion formed at the center of its top surface, the perforating process performed on the base portion of the base frame, the auxiliary leads each connected between opposite ends of the base portion and the heat-dissipating portion, and the main leads each having one end isolated from the heat-dissipating portion and the other end connected to the end of the base portion;
forming structures of the auxiliary leads and main leads such that first horizontal portions extend from the heat-dissipating portion along the same level with the top surface of the heat-dissipating portion by a predetermined length, vertical portions are bent downward from the first horizontal portions, and second horizontal portions extend from distal ends of the vertical portions along the same level with the bottom surface of the heat-dissipating portion;
forming a molding cap including a portion of the heat-dissipating portion and portions of the auxiliary leads and the main leads, the molding cap formed through molding such that the first horizontal portions extending along the same level with the top surface of the heat-dissipating portion and the chip mounting portion are partially exposed outside from the vertical portions together with the chip mounting portion; and
mounting a light emitting diode (LED) chip on the chip mounting portion and wire-bonding the LED chip and the first horizontal portions of the main leads to each other.
